(19) United States
(12) Patent Application Publication
(10) Pub. No.: US 2003/0230236 A1
(43) Pub. Date: Dec. 18, 2003

(54) Substrate processing apparatus and control method of inert gas concentration

(75) Inventor: Nobuyuki Shibayama, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/455,584

(22) Filed: Jun. 4, 2003

(30) Foreign Application Priority Data
Jun. 12, 2002 (JP) P/2002-171263

(51) Int. Cl. C30B 1/00

(52) U.S. Cl. 117/200

(57) ABSTRACT

Provided is a substrate processing apparatus capable of supplying pure water, the nitrogen gas concentration of which is stabilized. A pure water supply path is branched such that a dissolving part generates a high concentration pure water by dissolving nitrogen gas in pure water on one path, and a degassing part generates a low concentration pure water by degassing nitrogen gas from pure water on the other path. Pure water having a desired nitrogen gas concentration C can be supplied stably by sequentially measuring the nitrogen gas concentrations C1 and C2 on their respective paths, and mixing the high concentration pure water and low concentration pure water while the opening and closing of first and second pure water valves are adjusted to control first and second flows X1 and X2, so as to satisfy the following relationships: C1·X1+C2·X2=C·V; and X1+X2=V, wherein V is a total flow of pure water.

### BACKGROUND OF THE INVENTION

1. Field of the Invention

The present invention relates to a technique of controlling the inert gas concentration of a processing liquid used when a substrate such as a semiconductor wafer is subjected to a cleaning process.

2. Description of the Background Art

In a substrate cleaning process performed in the manufacturing process of a semiconductor device and the like, pure water, or a mixed liquid of pure water and hydrogen peroxide, ammonium etc. is used as a processing liquid. For example, a megasonic cleaning apparatus employs in some times such a processing liquid that is obtained by dissolving nitrogen gas, as an inert gas, in pure water under atmospheric pressure so as to have a concentration of approximately from 5 ppm to 20 ppm, in order to increase the efficiency of cleaning.

FIG. 4 is a diagram showing a conventional substrate processing apparatus 1000. The apparatus 1000 comprises mainly a pure water adjusting part 1001 and a processing part 1012.

The pure water adjusting part 1001 adjusts the nitrogen gas concentration of pure water to a predetermined concentration and then supplies it to the processing part 1012 that performs, for example, megasonic cleaning. The pure water so adjusted is obtained by dissolving nitrogen gas that is supplied from a nitrogen supply source 1004 provided as factory utility etc. via a nitrogen gas supply path 1005, in pure water that is supplied from a pure water supply source 1002 provided as factory utility etc. via a pure water supply path 1003.

The pure water adjusting part 1001 comprises a dissolving part 1006 for dissolving nitrogen in pure water supplied, a nitrogen concentration meter 1007 for measuring the nitrogen gas concentration of the pure water passing through the dissolving part 1006, a pressure gauge 1008 for measuring the pressure of nitrogen gas supplied through the nitrogen gas supply path 1005, a flow meter 1009 for measuring the flow of nitrogen gas, a valve 1010, and a control part 1011 for controlling the opening and closing of the valve 1010, based on measurements of the nitrogen concentration meter 1007.

FIG. 5 is a diagram showing a sequence of operating steps for dissolving nitrogen gas in the pure water adjusting part 1001, such that the nitrogen gas concentration of pure water has a predetermined desired concentration C. As shown in FIG. 5, in the pure water adjusting part 1001, firstly, the supply of nitrogen gas to the dissolving part 1006 is stopped, and an initial nitrogen gas concentration C0, corresponding to the nitrogen gas concentration in the state that no nitrogen gas is dissolved in pure water, (i.e., blank data) is taken by the nitrogen concentration meter 1007 (step S1001). Subsequently, a required dissolution concentration ΔC is found by subtracting the obtained initial nitrogen gas concentration C0 from the desired concentration C (step S1002). A desired gas pressure Pt to the required dissolution concentration ΔC is found from a chart indicating the relationship between pressure and dissolved concentration (step S1003). Next, a gas flow Ft to the desired gas pressure Pt is found from a chart indicating the relationship between pressure and flow (step S1004), and a gas pressure rising time T to the desired gas pressure Pt is found from a chart indicating the relationship between pressure and pressure rising time (step S1005).

Thus, the initial setting value is determined, and a nitrogen dissolving process based on this value is started (step S1006). Thereafter, the nitrogen concentration meter 1007 sequentially measures nitrogen gas concentration, and the gas flow and gas pressure are controlled proportionally based on the measured value (step S1007). This enables to supply pure water in which nitrogen gas of a desired concentration is dissolved.

However, the nitrogen dissolving process in the conventional substrate processing apparatus suffers from the following problem.

Specifically, the initial nitrogen gas concentration C0 in the pure water supplied to the dissolving part 1006 can vary depending on the pure water manufacturing circumstances and storage environment in the pure water supply source 1002. When the supplied pure water has a higher nitrogen gas concentration than the desired concentration C, the conventional method fails to reduce this concentration due to lack of the function of degassing nitrogen gas in the dissolving part 1006. In this case, it is therefore unavoidable that pure water having a higher nitrogen gas concentration than the desired concentration C is supplied to the processing part 1012.

For example, when performing a megasonic cleaning in the processing part 1012, even with the same input electric power, the physical energy intensity exerted on the substrate varies depending on the nitrogen gas concentration. Since this variation affects the effect of cleaning a substrate, the use of pure water having a higher nitrogen gas concentration than the desired concentration C lowers the percentage of removal of particles PRE or damages the substrate, resulting in poor manufacturing yield.

### SUMMARY OF THE INVENTION

The present invention is directed to a technique of controlling the inert gas concentration of a processing liquid used when performing a cleaning process in a substrate processing apparatus for processing a substrate such as a semiconductor wafer.

According to the present invention, a substrate processing apparatus includes:

(a) a processing part; and (b) a processing liquid supplying element. The processing part performs a predetermined processing of a substrate with a processing liquid. The processing liquid supplying element mixes first and second processing liquids to obtain mixed processing liquid and supplies the mixed processing liquid to the processing part. The first and second processing liquids have different concentrations of an inert gas.

With this configuration, a suitable processing liquid having a predetermined inert gas concentration can be supplied to the processing part by changing the proportions of the first and second processing liquids.

Preferably, the processing liquid supplying element of the substrate processing apparatus includes: a dissolving element; a degassing element; a first processing liquid flow adjusting element; a second processing liquid flow adjusting element; and a controlling element. The dissolving element obtains the first processing liquid by dissolving a first gas corresponding to the inert gas in a first liquid passing through a first supply path. The degassing element obtains the second processing liquid by degassing a second gas corresponding to the inert gas from a second liquid passing through a second supply path. The first processing liquid flow adjusting element adjusts a first flow that is the flow of the first processing liquid. The second processing liquid flow adjusting element adjusts a second flow that is the flow of the second processing liquid. The controlling element controls the first and second processing liquid flow adjusting elements.

With this configuration, the first and second processing liquids can be mixed in the state that the inert gas concentration difference therebetween is further increased. This enables to control the inert gas concentration of a processing liquid supplied to a desired value.

Accordingly, it is an object of the present invention to provide a substrate processing apparatus that can supply a processing liquid such as pure water by stabilizing the inert gas concentration of nitrogen gas and the like.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing a substrate processing apparatus according to one preferred embodiment of the present invention;

FIG. 2 is a diagram showing schematically the configuration of a dissolving part;

FIG. 3 is a diagram showing conceptually the principle that a nitrogen concentration meter makes a measurement;

FIG. 4 is a diagram showing a conventional substrate processing apparatus; and

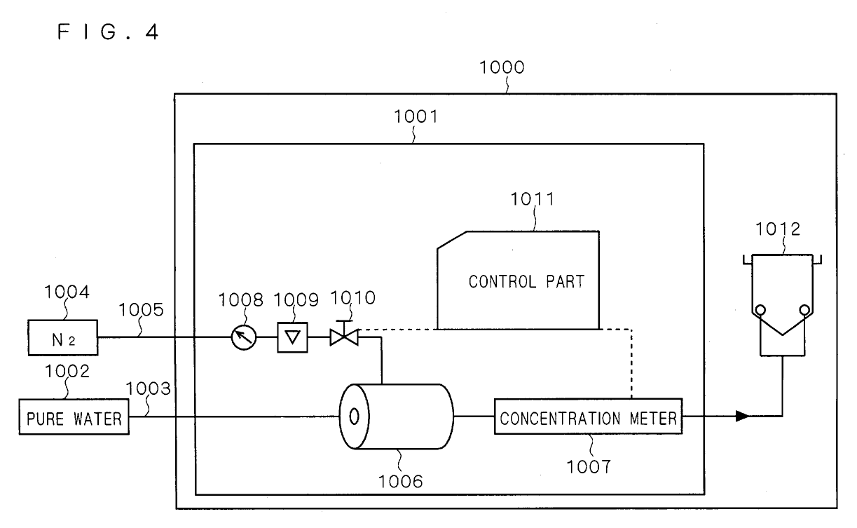

FIG. 5 is a diagram showing a sequence of operating steps for dissolving nitrogen gas in a pure water adjusting part.

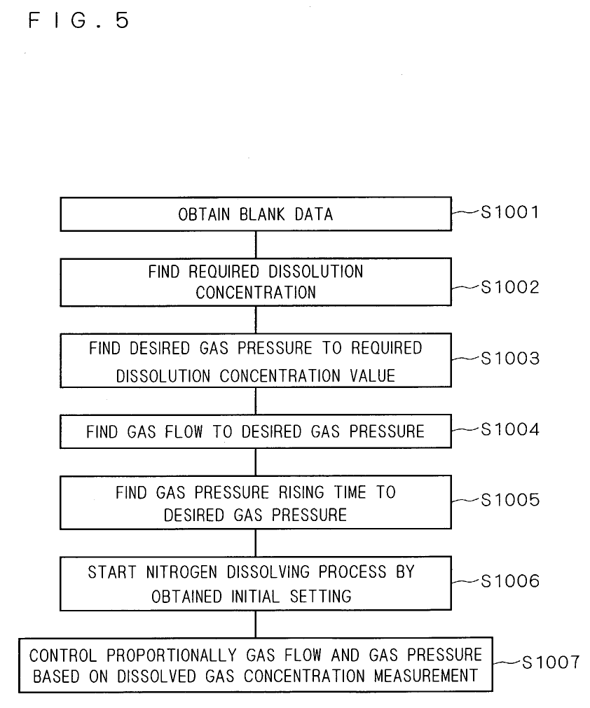

### DESCRIPTION OF THE PREFERRED EMBODIMENTS

### Overall Configuration

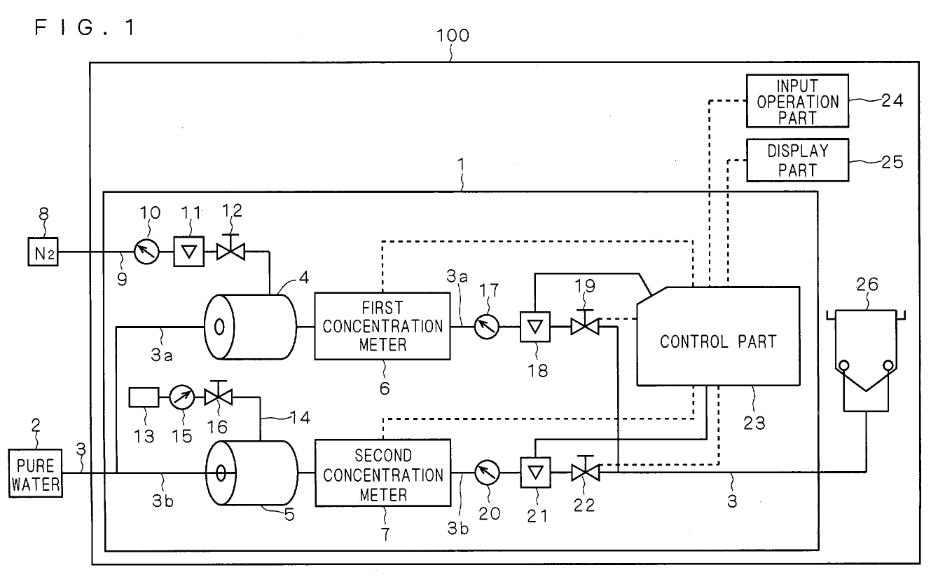

FIG. 1 is a diagram showing a substrate processing apparatus 100 according to one preferred embodiment of the present invention. The apparatus 100 comprises mainly a pure water adjusting part 1, an input operation part 24, a display part 25, and a processing part 26.

The pure water adjusting part 1 adjusts the nitrogen gas concentration of pure water, which is supplied from a pure water supply source 2 provided as a factory's utility or the like, via a pure water supply path 3, to a predetermined concentration and supplies the adjusted pure water to the processing part 26.

For purpose of this, the pure water adjusting part 1 comprises mainly a dissolving part 4 for dissolving nitrogen gas in pure water (a first supply liquid), a degassing part 5 for degassing nitrogen gas from pure water (a second supply liquid), a first nitrogen concentration meter 6 for measuring the nitrogen gas concentration of the pure water passing through the dissolving part 4, and a second nitrogen concentration meter 7 for measuring the nitrogen gas concentration of the pure water passing through the degassing part 5. In the pure water adjusting part 1, the pure water supply path 3 branches into a first supply path 3a via the dissolving part 4 and a second supply path 3b via the degassing part 5, and the two paths join again.

The dissolving part 4 and degassing part 5 have the same structural configuration except for equipments to be connected for dissolving or degassing nitrogen gas. These parts 4 and 5 function to change the nitrogen gas concentration of pure water by dissolving nitrogen gas in pure water or degassing nitrogen gas from pure water, through a hollow fiber type separation membrane having gas permeability and liquid impermeability.

To the dissolving part 4, nitrogen gas is supplied from a nitrogen gas supply source 8 provided as the factory's utility, via a nitrogen gas supply path 9. A first gas pressure gauge 10 for measuring the pressure of supplied nitrogen gas, a nitrogen gas flow meter 11 for measuring the flow of this nitrogen gas, and a first gas valve 12 capable of adjusting the flow of supplied nitrogen gas are disposed on the nitrogen gas supply path 9.

On the other hand, the pure water adjusting part 1 has a vacuum pump 13 that can perform evacuation in order to degas nitrogen gas in the degassing part 5. A second gas pressure gauge 15 for measuring the pressure obtained by the vacuum pump 13, i.e., the degree of vacuum, and a second gas valve 16 capable of adjusting the degree of vacuum are disposed on a nitrogen gas degassing path 14 extending from the degassing part 5 to the vacuum pump 13.

By adjusting the degree to which the first gas valve 12 is opened, the nitrogen gas flow is adjustable so that the rate of dissolution of inert gas into the first supply liquid is adjustable. Also, by adjusting the degree to which the second gas valve 16 is opened, the degree of vacuum is adjustable so that the rate of degasification of inert gas from the second supply liquid is adjustable.

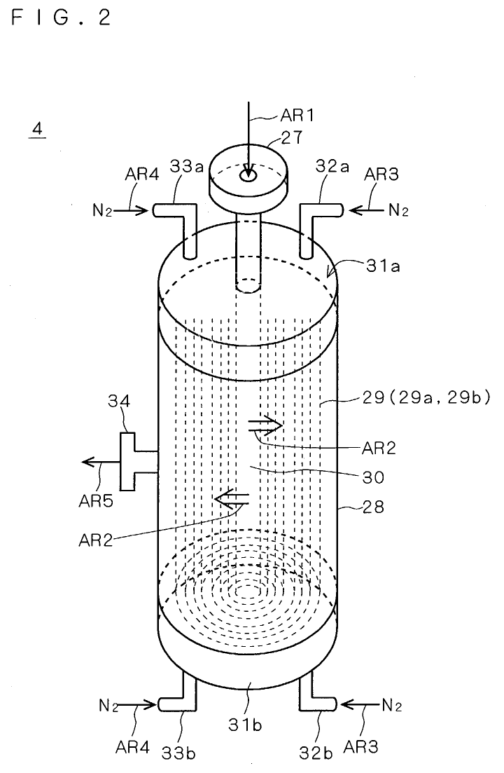

FIG. 2 is a diagram showing schematically the configuration of the dissolving part 4. Referring to FIG. 2, the dissolving part 4 comprises mainly (i) a body part 28 carrying out dissolving process; (ii) an intake port 27 that is disposed in a first end part 31a and intakes the pure water supplied from the first supply path 3a (FIG. 1) in the direction indicated by arrow AR1; (iii) a delivery port 34 that is disposed on the side surface of the body part 28 and delivers the pure water subjected to the dissolving processing in the direction indicated by arrow AR5; and (iv) a first gas inlet/outlet part 32 (32a, 32b) and a second gas inlet/outlet part 33 (33a, 33b) that are disposed in the first end part 31a and a second end part 31b such that they can independently supply or exhaust gas. In the dissolving part 4, the nitrogen gas passing through the nitrogen gas supply path 9 is supplied under pressure in the directions indicated by arrows AR3 and AR4, in the first and second gas inlet/outlet parts 32 and 33, respectively.

A water supply pipe 30 is disposed at the center in a longitudinal direction of the body part 28. The water supply pipe 30 is connected to the intake port 27 and supplies pure water in its periphery in the direction indicated by arrow AR2. In the periphery of the water supply pipe 30, a number of hollow fiber type separation membranes 29 in a thin cylindrical shape are arranged coaxially along the water supply pipe 30 of the body part 28. The hollow fiber type separation membrane 29 can be classified into a first hollow fiber type separation membrane 29a connected at its end part to the first gas input/output part 32, and a second hollow fiber type separation membrane 29b connected at its end part to the second gas input/output part 33, although their details are not shown.

In this preferred embodiment, nitrogen gas is supplied under pressure from both of the first and second gas input/output parts 32 and 33, as described above. Therefore, when the inside of the body part 28 is filled with the pure water supplied from the water supply pipe 30, there occurs a pressure difference between the inside and outside of the first and second hollow fiber type separation membranes 29a and 29b, so that only nitrogen gas molecules pass through the membranes 29a and 29b and then dissolved in the pure water. As the result, the pure water having the increased nitrogen gas concentration is delivered from the deliver port 34 in the direction indicated by arrow AR5.

The degassing part 5 has the same configuration as the dissolving part 4, except that the vacuum pump 13 reduces pressure in the direction opposite to arrows AR3 and AR4 in the first and second gas input/output parts 32 and 33, in order to evacuate nitrogen gas. By performing this evacuation, the inside of the first and second hollow fiber type separation membranes 29a and 29b is brought into a negative pressure state than the inside of the body part 28, and there occurs a pressure difference therebetween. Due to this pressure difference, the dissolved gas molecules in the pure water pass through from the outside of the first and second hollow fiber type separation membranes 29a and 29b, and these gas molecules are then subjected to degasification. Subsequently, in the degassing part 5, the pure water, the nitrogen gas concentration of which has been reduced, is delivered from the delivery port 34 in the direction indicted by arrow AR5.

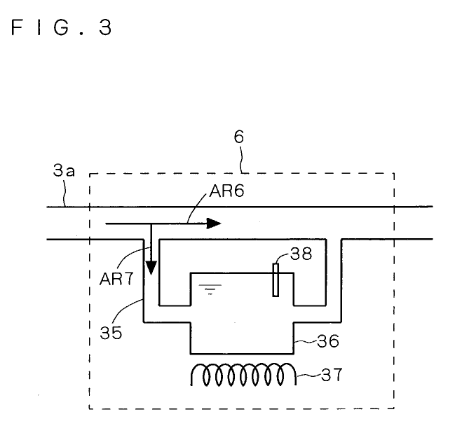

The first and second nitrogen concentration meters 6 and 7 have the same configuration and function. The former is disposed on the first and second supply paths 3a and 3b, in order to measure the concentration of nitrogen at certain time intervals. FIG. 3 is a diagram showing conceptually the principle that a measurement is made by the first nitrogen concentration meter 6, for example. The first nitrogen concentration meter 6 is configured as follows. That is, part of the pure water passing through the first supply path 3a in the direction indicated by arrow AR6 is branched by a branch pipe 35 into the direction indicated by arrow AR7, and the pure water is sampled into a measuring tank 36 at certain time intervals. Then, a heater 37 heats the sampled pure water in the measuring tank 36, and a probe 38 measures its temperature. The thermal conductivity of the sampled pure water is found from data of temperature changes so obtained. The thermal conductivity is increased with increasing the concentration of the dissolved nitrogen gas. Based on this correlation, the nitrogen gas concentration of the sampled pure water is obtained.

Further, the pure water adjusting part 1 has, on a downstream side than the first nitrogen concentration meter 6 on the first supply path 3a, (i) a first hydraulic pressure gauge 17 for measuring the hydraulic pressure of pure water in the first supply path 3a; (ii) a first pure water flow meter 18 for measuring the flow of this pure water; and (iii) a first pure water valve 19 for adjusting the flow. Likewise, the pure water adjusting part 1 has, on a downstream side than the second nitrogen concentration meter 7 on the second supply path 3b, (i) a second hydraulic pressure gauge 20 for measuring the hydraulic pressure of pure water in the second supply path 3b; (ii) a second pure water flow meter 21 for measuring the flow of this pure water; and (iii) a second pure water valve 22 for adjusting the flow. The first and second supply paths 3a and 3b join again after passing the first and second pure water valves 19 and 22, and become a single pure water supply path 3 that is connected to the processing part 26.

Furthermore, the pure water adjusting part 1 has a control part 23 that performs a predetermined control to maintain the nitrogen gas concentration of pure water at a desired concentration. The control part 23 is composed of a CPU, ROM, RAM and other memory. A predetermined program is read and executed so that the control part 23 controls the opening and closing of the first and second pure water valves 19 and 22, based on the measured values obtained by the first and second nitrogen concentration meters 6, 7, and the first and second pure water flow meters 18, 21. As the result, pure water having a desired nitrogen gas concentration is obtained and supplied to the processing part 26.

The input operation part 24 is, for example, a touch panel or keyboard, through which the operator of the substrate processing apparatus 100 performs a predetermined operation to input a certain instruction. The desired concentration of nitrogen gas is also inputted through the input operation part 24. The display part 25 is, for example, a display for displaying the contents of instructions from the operator and the operation circumstances of the substrate processing apparatus 100.

In an alternative, the substrate processing apparatus 100 may be configured as an apparatus arranged in one housing. In other alternative, the processing part 26 and pure water adjusting part 1 may be configured as a separate and independent apparatus. In a still other alternative, both of the input operation part 24 and display part 25, or these parts 24, 25 and the control part 23 of the pure water adjusting part 1 may be implemented by a general purpose computer.

### Control of Nitrogen Gas Concentration

Following is control of the nitrogen gas concentration of pure water in the pure water adjusting part 1. In this preferred embodiment, the pure water supplied from the pure water supply source 2, the nitrogen gas concentration of which is not adjusted, is branched into two paths to generate two types of pure water. That is, one type of pure water is generated on one path so as to have a higher nitrogen gas concentration by dissolving nitrogen gas (hereinafter referred to as “high concentration pure water”). The other type is generated on the other path so as to have a lower nitrogen gas concentration by degassing nitrogen gas (hereinafter referred to as “low concentration pure water”). Pure water having a predetermined nitrogen gas concentration is obtainable by mixing the desired proportions of the above-mentioned two types of pure water.

Therefore, in this preferred embodiment, the first nitrogen concentration meter 6 measures sequentially the nitrogen gas concentration of the high concentration pure water obtained by dissolving nitrogen gas in the dissolving part 4, and the second nitrogen concentration meter 7 measures sequentially the low concentration pure water obtained by degassing nitrogen gas in the degassing part 5. Based on the results of measurements, the control part 23 controls the flow of the high concentration pure water and the flow of the low concentration pure water in order to obtain pure water having a predetermined nitrogen gas concentration.

Concretely, the flow of the high concentration pure water and the flow of the low concentration pure water are controlled by adjusting the degree to which the first pure water valve 19 is opened in the first supply path 3a, and the degree to which the second pure water valve 22 is opened in the second supply path 3b. That is, the control part 23 controls the first and second pure water valves 19 and 22 so as to approximately establish the following relationships:

C1·X1+C2·X2=C·V (Equation 1)

and

X1+X2=V (Equation 2)

wherein V is the total flow of pure water supplied from the pure water supply source 2 via the pure water supply path 3; X1 is a first flow that is the flow of pure water branched into the first supply path 3a; X2 is a second flow that is the flow of pure water branched into the second supply path 3b; C1 is a first measured concentration that is the measured value of the nitrogen gas concentration in the first nitrogen concentration meter 6; C2 is a second measured concentration that is the measured value of the nitrogen gas concentration in the second nitrogen concentration meter 7; and C is a desired value of nitrogen gas concentration of pure water supplied to the processing part 26.

Here, the total flow V and desired concentration C are previously set as a fixed value, and the first and second measured concentrations C1 and C2 are obtained as a known value because they are measured at certain time intervals. Accordingly, every time the nitrogen gas concentration is measured, the first and second flows X1 and X2 satisfying Equation 1 and Equation 2 are determined. Therefore, the control part 23 adjusts the degree to which the first and second pure water valves 19 and 22 are opened, in order to obtain the first and second flows X1 and X2 so determined, thereby realizing the supply of pure water having a predetermined nitrogen gas concentration. In the event that one of the two flows is fixed for any reason, the other flow can be determined unequivocally.

The nitrogen gas concentration of unadjusted pure water supplied from the pure water supply source 2 varies depending on the factor derived from the pure water supply source 2. It is however possible to cancel the influence of such variation and therefore obtain the first flow X1 and second flow X2 that always satisfy Equation 1 and Equation 2 in the following manner. A high concentration pure water having a nitrogen gas concentration sufficiently higher than the desire concentration C is generated in the dissolving part 4, and a low concentration pure water having a nitrogen gas concentration sufficiently lower than the desire concentration C is generated in the degassing part 5, such that the desired concentration C is always between the first measured concentration C1 and second measured concentration C2. Since the amount of the flows to be mixed is determined based on the nitrogen gas concentration after performing dissolution or degasification, pure water having a predetermined nitrogen gas concentration is obtainable without controlling sequentially the dissolution and degasification in the dissolving part 4 and degassing part 5, respectively.

Even when the desired concentration C is changed because the processing object in the processing part 26 is changed, first and second flows X1 and X2 under new conditions can be obtained quickly by satisfying Equation 1 and Equation 2. This permits a quick change in the amount of a mixture of high concentration pure water and low concentration pure water.

As described above, the pure water adjusting part 1 of the substrate processing apparatus 100 can stably supply pure water, the nitrogen gas concentration of which is maintained at a predetermined value, to the processing part 26.

### Modifications

In the foregoing preferred embodiment, the pure water supply path 3 branches and then joins in the pure water adjusting part 1. This is not essential in the present invention. For example, the pure water supply path 3 may branch and join at other location in the substrate processing apparatus 100, or at the outside of the apparatus 100.

In an alternative, the nitrogen gas concentrations of pure water supplied to the dissolving part 4 and degassing part 5 may be measured in order to stabilize the concentrations of high concentration pure water and low concentration pure water based on the concentrations before and after dissolution and degasification. This further stabilizes the concentration of the pure water obtained by mixing the two types of pure water.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus comprising:
a processing part for performing a predetermined processing of a substrate with a processing liquid; and
a processing liquid supplying element for mixing first and second processing liquids to obtain mixed processing liquid and supplying said mixed processing liquid to said processing part, said first and second processing liquids having different concentrations of an inert gas.

2. The substrate processing apparatus according to claim 1 wherein
said processing liquid supplying element comprises:
a dissolving element for obtaining said first processing liquid by dissolving a first gas corresponding to said inert gas in a first liquid passing through a first supply path; and
a degassing element for obtaining said second processing liquid by degassing a second gas corresponding to said inert gas from a second liquid passing through a second supply path.

3. The substrate processing apparatus according to claim 2 wherein
said processing supplying element further comprises:
a first processing liquid flow adjusting element for adjusting a first flow that is the flow of said first processing liquid;
a second processing liquid flow adjusting element for adjusting a second flow that is the flow of said second processing liquid; and
a controlling element for controlling said first and second processing liquid flow adjusting elements.

4. The substrate processing apparatus according to claim 3 further comprising:
a first concentration measuring element for measuring concentration of said first gas in said first processing liquid; and
a second concentration measuring element for measuring concentration of said second gas in said second processing liquid;
wherein said controlling element controls said first flow and said second flow based on a first measured concentration and a second measured concentration, respectively,
said first measured concentration being a measured value of the concentration of said first gas in said first concentration measuring element, and said second measured concentration being a measured value of the concentration of said second gas in said second concentration measuring element.

5. The substrate processing apparatus according to claim 4 wherein
said controlling element controls said first and second processing liquid flow adjusting elements so as to approximately satisfy the following relationship:
C1·X1+C2·X2=C·V
where
C1 is said first measured concentration,
C2 is said second measured concentration,
X1 is said first flow,
X2 is said second flow,
C is a target value of the concentration of said inert gas in said mixed processing liquid obtained by mixing, and
V is the total flow of said mixed processing liquid.

6. The substrate processing apparatus according to claim 5 wherein
said first and second processing liquids are supplied so as to satisfy the following relationship:
X1+X2=V.

7. A method of controlling an inert gas concentration in a processing liquid in an apparatus performing a predetermined processing with said processing liquid, said method comprising the step of:
(a) mixing first and second processing liquids to obtain mixed processing liquid and supplying said mixed processing liquid to a processing part, said first and second processing liquids having different concentrations of an inert gas.

8. The method according to claim 7 further comprising the steps of:
(b-1) obtaining said first processing liquid by dissolving a first gas corresponding to said inert gas in a first liquid passing through a first supply path; and
(b-2) obtaining said second processing liquid by degassing a second gas corresponding to said inert gas from a second liquid passing through a second supply path.

9. The method according to claim 8 further comprising the steps of:
(c-1) adjusting a first flow that is the flow of said first processing liquid;
(c-2) adjusting a second flow that is the flow of said second processing liquid; and
(d) controlling adjustments of flows in the steps (c-1) and (c-2).

10. The method according to claim 9 further comprising the steps of:
(e-1) measuring concentration of said first gas in said first processing liquid; and
(e-2) measuring concentration of said second gas in said second processing liquid,
wherein the control in the step (d) is effected based on first and second measured concentrations, said first measured concentration being a measured value of the inert gas concentration in the step (e-1), and said second measured concentration being a measured value of the inert gas concentration in the step (e-2).

11. The method according to claim 10 wherein
the control in the step (d) is effected so as to approximately satisfy the following relationship:
C1·X1+C2·X2=C·V
where
C1 is said first measured concentration,
C2 is said second measured concentration,
X1 is said first flow,
X2 is said second flow,
C is a target value of the concentration of said inert gas in said mixed processing liquid obtained by mixing, and
V is the total flow of said mixed processing liquid.

12. The method according to claim 11 wherein
said first and second processing liquids are supplied so as to satisfy the following relationship:
X1+X2=V.
